(19) United States
(12) Patent Application Publication
(10) Pub. No.: US 2003/0079165 A1
(43) Pub. Date: Apr. 24, 2003

(54) Effective use of parallel scan for identically instantiated sequential blocks

(76) Inventors: Niall Ffrench, San Diego, CA (US); Arjun Punshi, San Diego, CA (US)

Correspondence Address: Hughes Electronics Corporation, Patent Docket Administration, Bldg. 1, Mail Stop A109, P.O. Box 956, El Segundo, CA, 90245-0956, US

(21) Appl. No.: 10/053,389

(22) Filed: Oct. 23, 2001

(51) Int. Cl. G01R 31/28

(52) U.S. Cl. 714/726

(57) ABSTRACT

A method and system employing a plurality of modules having a scan chain combiner coupled to the output of each one of the plurality of modules. The scan chain combiner selects one value per scan chain received from said plurality of modules, wherein the value is indicative of errors in at least one of the plurality of modules. An output mux for communicating the value to a tester via a plurality of chip outputs is coupled to the scan chain combiner.

### FIELD OF THE INVENTION

The present invention relates to integrated circuit testing. Specifically, the invention relates to a method and apparatus for performing scan testing on an Application Specific Integrated Circuit (ASIC).

### BACKGROUND OF THE INVENTION

Automatic test equipment (ATE) also known as a tester is used to inspect assembled printed circuit boards (PCB's) and/or integrated circuits (ICs). In particular, “in-circuit” ATE is used for detecting and reporting faults on newly assembled ICs in the production line. A test program including a series of test steps controls the actions of the ATE, telling it how to test the IC and how to report faults. A typical in-circuit test program inspects the IC to verify correct assembly, i.e. the program is designed to confirm that each part is the correct part and that all of its pins are properly connected to the printed wiring. In the ideal case, each test step in the test program is devoted to the inspection of one component.

Each test step stimulates and evaluates responses from a named component associated with the test step. If the test produces an out-of-limit analog response or an unexpected digital response, the tester rejects the IC and reports the named component associated with the test step. A rework operator can easily examine the IC and return it to the tester for retest. An information system may collect failure information over a period of time and supply statistics to a quality improvement process.

An in-circuit test step for a complex digital integrated circuit on a printed circuit board specifies a connected sequence of digital test vectors, with one vector following the next in a defined and repeatable sequence. Each digital test vector in the sequence specifies, for a given instant in time, the stimulus signals the tester is to apply to input pins of the IC and in addition, the response signals that the tester is to expect from a good IC that is correctly installed on the PCB.

A valid sequence of digital test vectors for a particular named component must be stable and must comprehensively cover static faults on IC pins. “Stable” means that when the tester applies this sequence to an IC that is functioning correctly, the tester will never mistakenly reject the IC and report a component on the IC as being defective. “Comprehensively” means that when the tester applies the sequence to an IC on which the associated named component is incorrect, is nonfunctional, or defective, the tester will reject the IC and report the named component. “Static” means that the fault being detected persists throughout the test vector sequence. For example, an open input pin would deliver a constant level to the IC under test rather than allow the pin to deliver the bits from the stimulus part of the vector, and an open output pin would deliver a constant level to the tester rather than conduct the actual highs and lows that emanate from the stimulated IC.

In testing the IC, the tester is testing a plurality of registers associated with a respective module. As more circuitry is packed onto an IC, redundancy in IC testing becomes more common. Very often, the modules are duplicated on an IC. However, because the modules are tested consecutively, long testing times usually are necessary.

One way to avoid a long testing time is to increase the tester's memory. However, this may not be beneficial in cases where the scan chains of the tester cannot be increased.

Another method to reduce long testing times is to increase the number of scan chains and tester memory. However, the cost of retooling the tester and down time to do this may prove to be prohibitive in a field that requires low cost and “on time” testing.

Therefore, a need arises for an IC that allows parallel testing of modules without a need to retool the tester or require additional memory.

### SUMMARY OF THE INVENTION

The above objectives are substantially achieved by a system and method utilizing an Integrated Circuit (IC) in accordance with the principles of the present invention. The method and system includes a plurality of modules having a scan chain combiner coupled to the outputs of each one of the plurality of modules. The scan chain combiner selects one value per scan chain received from said plurality of modules, wherein the value is indicative of errors in at least one of the plurality of modules. An output mutliplexer (mux) for communicating the value to a tester via a plurality of chip outputs is coupled to the scan chain combiner.

### BRIEF DESCRIPTION OF THE DRAWINGS

The details of the present invention can be readily understood by considering the following detailed description in conjunction with the accompanying drawings, and with:

FIG. 1 depicts an illustrative embodiment of an Application Specific Integrated Circuit in accordance with the present invention;

FIG. 2 depicts a flow diagram illustrating an exemplary test data operation that can be performed by the ASIC in accordance with an embodiment of the present invention;

FIG. 3 depicts a flow diagram illustrating another exemplary test data operation that can be performed by the tester on the ASIC in accordance with an embodiment of the present invention; and

FIG. 4 is an illustrative embodiment of the plurality of modules in accordance with the present invention of FIG. 1.

To facilitate understanding identical reference numerals have been used, where possible, to designate identical elements that are common to the figures.

### DETAILED DESCRIPTION OF THE INVENTION

The following description will illustrate the present invention using an exemplary Application Specific Integrated Circuit (ASIC) design as applied to scan vector testing. It should be appreciated, however, that the invention is not limited for use with any particular type of circuit or design process. For example, although well suited for externally driven scan applications, the novelty of the invention is particularly well suited for use in Built In Self Test (BIST) applications.

In addition, the term “scan chain” is intended to include a set of flip flops or other logic circuit elements configured to permit testing of combinational logic or other circuitry. For example, scan chains may be connected in a manner that allows shifting in of test vectors which can be applied to combinational logic between the scan chains.

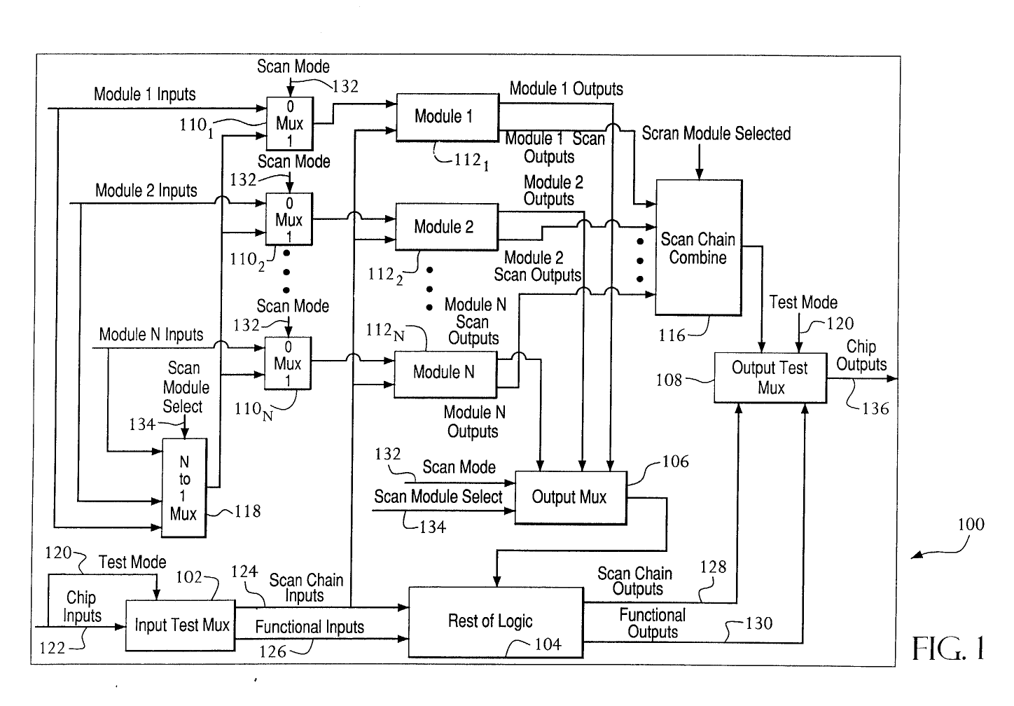

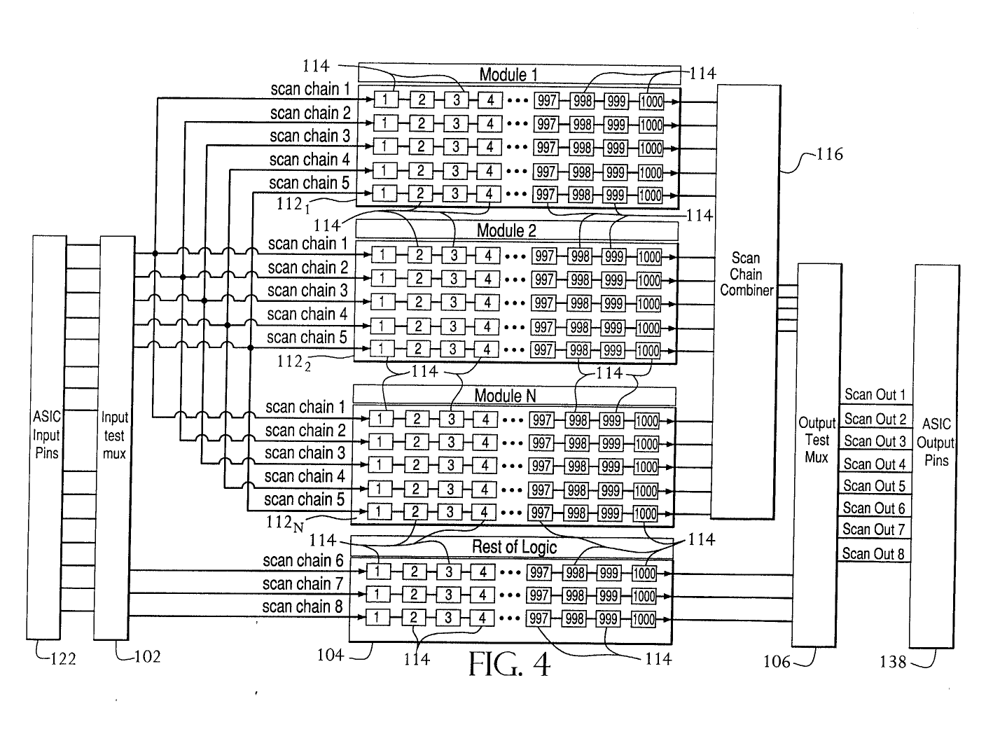

FIG. 1 depicts an illustrative embodiment of an Application Specific Integrated Circuit in accordance with the present invention. Specifically ASIC 100 comprises an input test mux 102 having inputs and outputs, a rest of logic portion 104 having inputs and outputs, an output mux 106 having inputs and outputs and an output test mux 108 having inputs and outputs. The ASIC 100 further comprises a first mux 110₁, a second mux 110₂ up to N mux 110_{N} (hereinafter referred to as first plurality of muxes 110) which receives outputs from module 1, module 2 through module N, respectively, as shown. The ASIC 100 also includes a first module 112₁ including a first plurality of registers 114₁ (see FIG. 4), a second module 112₂ including a second plurality of registers 114₂ up to N module 112_{N} including N plurality of registers 114_{N} (hereinafter referred to as module 112 and plurality of registers 114), a scan chain combiner 116 which receives outputs from modules 112₁ through 112_{N}, and an optional mux 118. The input test mux 102 receives a test mode signal 120 and a plurality of chip inputs 122, and outputs a plurality of scan chain inputs 124, a plurality of functional inputs 126 which are received by the logic portion 104, a plurality of scan chain outputs 128 and functional outputs 130 to the output test mux 108. A scan mode select signal 132 and a scan module select signal 134 are input to the output mux 106. An output from scan chain combiner 116 along with scan chain outputs 128 and functional outputs 130 are received by output test mux 108, which outputs a plurality of chip outputs 136.

Further details of the ASIC 100 shown in FIG. 1 and the relationship of its components will now be described.

The plurality of chip inputs 122, which are provided from pins serving as an interface between the internal logic of the ASIC 100 and the outside world, are coupled to the input test mux 102. One of these pins provides the test mode signal 120 of the chip. Input test mux 102 can be a conventional test mux that is standard on ASICS and serves to put the chip in test mode. Specifically, when the test mode signal 120 is provided, the ASIC 100 is put into testing mode via input mux 102. The pins of the ASIC 100 have different functions based on the mode of the chip. For example, when the ASIC 100 is in functional mode, the input levels and output levels at the pins of the ASIC 100 may have a different reading and different function as opposed to when the ASIC 100 is in testing mode.

The plurality of functional inputs 126 are coupled between the output of the input test mux 102 and the input of the rest of the logic 104. The plurality of functional inputs 126 are inputs from the plurality of chip inputs 122 when the ASIC 100 is in its normal mode, that is, the chip is operating in a manner of accomplishing the function for which it was designed. The rest of the logic 104 may be conventional circuitry that assists the ASIC 100 in performing the task for which it was designed.

The plurality of scan chain inputs 124 is also coupled to the rest of the logic 104 and to the inputs of first module 112₁, second module 112₂ up to N module 112_{N}. With this connection, test vectors are received from the plurality of chip inputs 122 and routed to first module 112₁, second module 112₂ up to N module 112_{N}. Since each module performs the same function, it is more efficient to test each module at the same time. That is, the modules 112 are tested in parallel, but each one of the plurality of registers 114₁, 114₂ up to 114_{N} associated with a respective module 112 is tested sequentially.

In an embodiment of the invention, as illustrated in FIG. 4, each one of the plurality of scan chain inputs 124 is balanced to the number of modules and/or registers. For example, the scan chain inputs to each one of the modules 112 are from the same source pin, thus each of the modules 112 will be processing the same test vector at the same time. The number of scan chains used for the modules 112 versus the rest of the logic 104 is based on the ratio of registers in one of the modules 112 to the number of registers in the rest of the logic 104. The goal is to closely balance the scan chain length across all scan chains to reduce the tester's time. The scan chain length can be the number of registers in a module. For example, in this case, the scan chain length would be 1,000 which represents the 1,000 registers in each module. Specifically, if the tester only supported 8 scan chains and 1 of the modules 112 contained 5000 registers and the rest of the logic contained 3000 registers, there would be a total of 8000 registers to balance between the 8 scan chains. Therefore, each of the 8 scan chains would have 1000 registers each, with 5 scan chains in each of the modules 112 and 3 scan chains in the rest of the logic 104. FIG. 4, shows that the calculation of the scan chain length which is 1000 is independent of the number of modules 112.

As discussed briefly above, the module 1 input, module 2 input up to module N inputs are provided to a respective first mux 101₁, second mux 110₂ up to N mux 110_{N} and to optional mux 118. The module 1 input, module 2 input up to module N inputs may be derived from the plurality of chip inputs 122, the rest of the logic 104 and/or from a previous module N input. For example, a module N input source may be a module N−1, N−2, etc. input source.

The first mux 110₁, second mux 110₂ up to N mux 110_{N} allow the selection of functional inputs or scan specific chain inputs. The scan specific inputs are only needed if the source of the signals are different for each of the first module 112₁, second module 112₂ up to N module 112_{N}. The goal is to make all of the modules look identical or substantially identical and have the same inputs in scan mode. For example, if all the modules including first module 112₁, second module 112₂ up to N module 112_{N} has a different test vector, then the test vectors have to go through first mux 110₁, second mux 110₂ up to N mux 110_{N} in order to route the test vectors to the respective module. In addition, optional mux 118, which can be an N by 1 mux, may be used to select which of the module 1 input, module 2 input up to module N inputs is used to generate test vectors. However, if only one module input is used to generate test vectors, then optional mux 118 can be eliminated. For example, if module 1 is always used to generate test vectors, optional mux 118 can be eliminated, and module 1 input would always feed first mux 110₁, second mux 110₂ up to N mux 110_{N}.

Scan mode select signal 132 is coupled to each of one of the first mux 110₁, second mux 110₂ up to N mux 110_{N} and output mux 106 as shown. The scan mode select signal 132 allows the plurality of registers 114 to be tested and is a global signal which informs each one of the plurality of registers 114 that the register will be tested.

The output of the first mux 110₁, second mux 110₂ up to N mux 110_{N} is coupled to a respective first module 112₁, second module 112₂ up to N module 112_{N}. This configuration as previously discussed allows first module 112₁, second module 112₂ up to N module 112_{N} to have the same module inputs during testing to make sure all the modules are being stimulated in an identical manner.

The scan chain outputs of the respective first module 112₁, second module 112₂ up to N module 112_{N} are coupled to the scan chain combiner 116 via a respective module 1 scan outputs, module 2 scan outputs up to a module N scan outputs. The module 1 scan output, module 2 scan output up to a module N scan output are the output signals of the plurality of registers 114. Specifically, the signals are the output signals of the test vectors after being processed by the plurality of registers 114. More specifically, each module has an output value. Since all the modules are identical or substantially identical, the output values for each of the modules should, likewise, be the same. However, if the values are different for the different modules while the test vector input values are the same, it indicates that there is an error condition for the modules.

The ASIC 100 can employ majority voting technique which will be described in greater detail below, that uses the output value that is the minority as the result. For instance, if first module 112₁ outputted a zero scan value, second module 112₂ outputted a one scan value and N module 112_{N} outputted a zero scan value, the ratio would be two zero scan values to one scan value. Hence, the scan chain combiner 116 would output a one scan value to output test mux 108. The tester would compare the scan chain combiner 116 output with an expected value. Any deviation between the two values would require additional testing to determine which of the modules 112 is defective.

Conventionally, the output of the module would be coupled to a chip output. However, since testing is done in parallel, the tester would not know how to read multiple output values from the various modules. Hence, the scan chain combiner 116 enables the tester to receive a single output from multiple modules.

The outputs of the respective first module 112₁, second module 112₂ up to N module 112_{N} are coupled to the output mux 106 via a respective module 1 output, module 2 output up to a module N output. In certain instances, module 1, module 2 and module N outputs are required to stimulate circuits or registers in the rest of the logic 104. In order for this to occur properly, the source of that stimulation is required to be selected because when a test pattern is generated only one of the modules 112 generates the pattern for the tester. Testers are not capable of doing parallel testing for ASICS so the tester has to be fooled into thinking that only one of the modules 112 is generating the pattern. The module output signals are removed from the N−1 modules, and the remaining N module signal is communicated to the rest of the logic 104 to stimulate circuits and/or registers.

The scan module select signal 134 is provided to the optional mux 118, the output mux 106 and the scan chain combiner 116 and provides a scan module select signal which selects the a particular module for testing or generating patterns. The signal may be used when a failure or error is detected in modules. Each module would then be tested individually using the scan module select signal 134 to determine the modules that failed. When the scan module select signal 134 is used with the optional mux 118, any of the module inputs can be communicated to any of the different modules. In combination with output mux 106, the scan module select signal 134 may be used to select which one of the module output signals is communicated to the rest of the logic 104. Having a scan module select signal reduces the requirement for having additional chip inputs in order to access specific modules. The number of chip inputs for the scan module select can be calculated by utilizing equation 1 as follows:

Number of scan module select signals=Roundup of log₂(N+1) (1)

The extra option in the log₂ argument in equation 1 will be used to select all of the modules 112 in the scan chain combiner 116.

The rest of logic 104 is coupled to the output test mux 108 via the plurality of scan chain outputs 128 and plurality of functional outputs 130. The scan chain combiner output is also coupled to the output test mux 108. Output test mux 108 is similar in function to input test mux 102 and muxes the functional outputs with the test outputs. The appropriate output is selected determinative of what mode the output test mux 108 is in either test or normal mode. The output result from the output test mux 108 is communicated to the plurality of chip outputs 136 which are pins serving as an interface between the ASIC 100 and the outside world.

Table 1 described below illustrates an example of majority voting logic performed in accordance with an embodiment of the present invention.

TABLE 1
MAJORITY VOTING LOGIC (N EVEN)

| Number of Bits = 1 | Output |
|---|---|
| 0 | 0 (All Modules Agree on “0”) |
| 1 | 1 |
| 2 | 1 |
| 3 | 1 |
| 4 | 1 |
| N/2 − 1 | 1 |
| N/2 | 1 or 0 |
| N/2 + 1 | 0 |
| N − 1 | 0 |
| N | 1 (All Modules Agree on “1” |

Specifically, Table 1 comprises a majority voting logic for an even amount of modules. More specifically, the values of the module scan outputs are compared per scan chain (i.e. all of the scan chain 1 outputs from each of the N modules are compared with each other, and so on), and the value either a zero or one that is less than 50% is chosen as the output value by the scan chain combiner 116. The number of bits equal to one indicates how many of the scan chain outputs per scan chain from each of the N modules agree on the value of one. The output field represents the value that is sent out by the scan chain combiner 116.

In Table 1, the first entry under the Number of Bits=1 field is a zero. This indicates that all of the modules produced the same result. Therefore, there were no errors. Since all of the modules produced the same result, a zero value, that value will be outputted by the scan chain combiner 116. The zero value as an output is assumed to be the correct value for the modules. Any module that deviates from a zero output will be assumed to be in error.

The second entry under the Number of Bits=1 field is a one. This indicates that out of the N modules one of the modules outputted a one value. Since all the other modules outputted a zero value, the scan chain combiner 116 will output a one value to indicate to the tester that a possible error was detected.

The third entry under the Number of Bits=1 field is a two. This indicates that out of the N modules two of the modules outputted a one value. Since all the other modules outputted a zero value, the scan chain combiner 116 will output a one value to indicate to the tester that a possible error was detected.

The fourth entry under the Number of Bits=1 field is a three. This indicates that out of the N modules three of the modules outputted a one value. Since all the other modules outputted a zero value, the scan chain combiner 116 will output a one value to indicate to the tester that a possible error was detected.

The fifth entry under the Number of Bits=1 field is a four. This indicates that out of the N modules four of the modules outputted a one value. Since all the other modules outputted a zero value, the scan chain combiner 116 will output a one value to indicate to the tester that a possible error was detected.

The sixth entry under the Number of Bits=1 field is N/2−1. This indicates that out of the N modules one less than half of the modules outputs a one value. Since all the other modules outputted a zero value, the scan chain combiner 116 will output a one value to indicate to the tester that a possible error was detected.

The seventh entry under the Number of Bits=1 field is N/2. This indicates that out of the N modules half of the modules outputted a zero value and the other half outputted a one value. Since the modules output a one and zero equally, the scan chain combiner 116 will output either a one value or a zero value. It's possible that the tester may receive the incorrect information. However, this is, typically, a very unlikely scenario.

The eighth entry under the Number of Bits=1 field is N/2+1. This indicates that out of the N modules more than half of the modules outputted a one value. Since all the other modules outputted a zero value, the scan chain combiner 116 will output a zero value to indicate to the tester that a possible error was detected. In this scenario, the majority of the modules believe the correct value is a one and the scan chain combiner 116 assumes the majority is correct. When all the modules do not give the same output, the scan chain combiner 116 will propagate the incorrect value to the output test mux 108 and then through the chip output pin 136 to the tester.

The ninth entry under the Number of Bits=1 field is N−1. This indicates that out of the N modules all of the modules except one outputted a one value. Since all the other modules outputted a one value, the scan chain combiner 116 will output a zero value to indicate to the tester that a possible error was detected.

The tenth entry under the Number of Bits=1 field is N. This indicates that out of the N modules all of the modules outputted a one value. Since there were no errors, the scan chain combiner 116 will output a one value.

If the value outputted by the scan chain combiner 116 is incorrect, the tester will know because the tester will compare the scan chain combiner's 116 output value with an expected value. Any deviation from the expected value indicates an error.

Table 2 discussed in more detail below illustrates an example of majority voting logic performed in accordance with an embodiment of the present invention.

TABLE 2
MAJORITY VOTING LOGIC (M ODD)

| Number of Bits = 1 | Output |
|---|---|
| 0 | 0 (All Modules Agree on “0”) |
| 1 | 1 |
| 2 | 1 |
| 3 | 1 |
| 4 | 1 |
| (N − 1)/2 − 1 | 1 |
| (N − 1)/2 | 1 |
| (N − 1)/2 + 1 | 0 |
| N − 1 | 0 |
| N | 1 (All Modules Agree on “1” |

Specifically, Table 2 comprises a majority voting logic for an odd amount of modules. More specifically, the values of the module scan outputs are compared per scan chain since there can be multiple scan chain outputs from all the N modules 112, and the value either a zero or one that is less than 50% is chosen as the output value by the scan chain combiner 116. The number of bits equal to one indicates how many of the scan chain outputs per scan chain from each of the N modules 112 agree on the value of one. The output field represents the value that is sent out by the scan chain combiner 116.

In Table 2, the first entry under the Number of Bits=1 field is a zero. This indicates that all of the modules produced the same result. Therefore, there were no errors. Since all of the modules produced the same result, a zero value, that value will be outputted by the scan chain combiner 116. The zero value as an output is assumed to be the correct value for the modules. Any module that deviates from a zero output will be assumed to be in error.

The second entry under the Number of Bits=1 field is a one. This indicates that out of the N modules one of the modules outputted a one value. Since all the other modules outputted a zero value, the scan chain combiner 116 will output a one value to indicate to the tester that a possible error was detected.

The third entry under the Number of Bits=1 field is a two. This indicates that out of the N modules two of the modules outputted a one value. Since all the other modules outputted a zero value, the scan chain combiner 116 will output a one value to indicate to the tester that a possible error was detected.

The fourth entry under the Number of +Bits=1 field is a three. This indicates that out of the N modules three of the modules outputted a one value. Since all the other modules outputted a zero value, the scan chain combiner 116 will output a one value to indicate to the tester that a possible error was detected.

The fifth entry under the Number of Bits=1 field is a four. This indicates that out of the N modules four of the modules outputted a one value. Since all the other modules outputted a zero value, the scan chain combiner 116 will output a one value to indicate to the tester that a possible error was detected.

The sixth entry under the Number of Bits=1 field is (N−1)/2−1. This indicates that out of the N modules less than the majority of the modules outputs a one value. Since the majority of the modules outputted a zero value, the scan chain combiner 116 will output a one value to indicate to the tester that a possible error was detected.

The seventh entry under the Number of Bits=1 field is (N−1)/2. This indicates that out of the N modules less than the majority the modules outputted a zero value while the majority of the modules outputted a one value. The scan chain combiner 116 will output a value of zero to indicate to the tester that a possible was detected.

The eighth entry under the Number of Bits=1 field is (N−1)/2+1. This indicates that out of the N modules more than half of the modules outputted a one value. Since the minority of the modules outputted a zero value, the scan chain combiner 116 will output a zero value to indicate to the tester that a possible error was detected. In this scenario, the majority of the modules believe the correct value is a one and the scan chain combiner 116 assumes the majority is correct. When all the modules do not give the same output, the scan chain combiner 116 will propagate the incorrect value to the output test mux 108 and then through the chip out pin 136 to the tester.

The ninth entry under the Number of Bits=1 field is N−1. This indicates that out of the N modules all of the modules except one outputted a one value. Since all the other modules outputted a one value, the scan chain combiner 116 will output a zero value to indicate to the tester that a possible error was detected.

The tenth entry under the Number of Bits=1 field is N. This indicates that out of the N modules all of the modules outputted a one value. Since there were no errors the scan chain combiner 116 will output a one value.

Unlike the situation with Table 1 in which half the modules can output a one value while the other half can output a zero value, when the number of modules are odd the situation will never occur where scan chain combiner 116 can arbitrarily select a value.

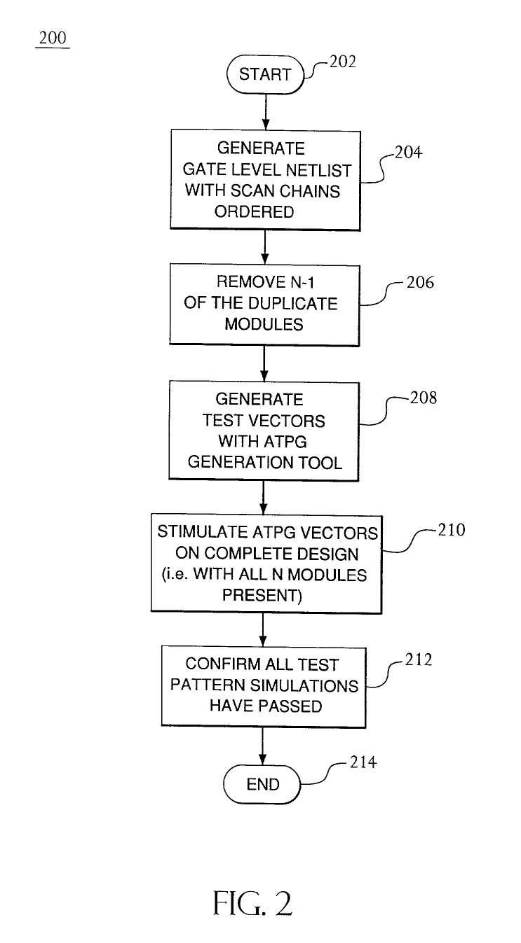

FIG. 2 depicts a flow diagram illustrating an exemplary test data operation that can be performed by the ASIC in accordance with an embodiment of the present invention. Specifically, the method 200 illustrates the flow to generate test patterns which will be simulated on a computer test platform. The method 200 of FIG. 2 is initiated at step 202 and proceeds to step 204 where the netlist has been generated by the synthesis tool and has all of the scan chains ordered. The method 200 then proceeds to step 206.

At step 206 N−1 modules are removed from the original netlist for initial test purposes. The Automated Test Pattern Generator (ATPG) tool generates test patterns in the art of ASIC development attempting to test all possible logic combinations and uncover any faults in the ASIC 100. The ATPG tool is not capable of understanding multiple scan chain outputs from a single scan chain input as is the configuration of this design. Therefore, by removing N−1 modules, the tester only detects one module which satisfies the ATPG tool's condition for only one scan chain output. That is, the ATPG tool is programmed to test one module at a time, which is all that the ATPG tool is capable of.

At step 208 test patterns are generated via the ATPG tool. The test patterns are used to stimulate the ASIC 100 and detect errors in one of the identical modules. Specifically, errors in anyone of the plurality of registers 114 is detected. More specifically, a predetermined value is expected at the scan chain output of a module. A deviation from that value indicates an error within that module and classifying the ASIC 100 as being defective. The method 200 then proceeds to step 210.

At step 210 the N−1 modules are put back into the netlist. That is, although ATPG tool can only generate test patterns with one module present, the ASIC 100 is designed so that all the modules are tested simultaneously. The N modules are tested in parallel where the time it takes to test all N modules is the same time it takes to test just one of the N modules. The method 200 then proceeds to step 212.

At step 212 the designer confirms all the test pattern simulations have passed within the computer simulation environment. Once the computer simulations of the ASIC netlist are finished, we can proceed to run the test patterns on the actual device to detect any flaws in the ASIC 100. (The assumption is the ASIC netlist is modeled perfectly with no flaws and therefore the computer simulations will pass without errors.) The method 200 proceeds to step 214 where it ends.

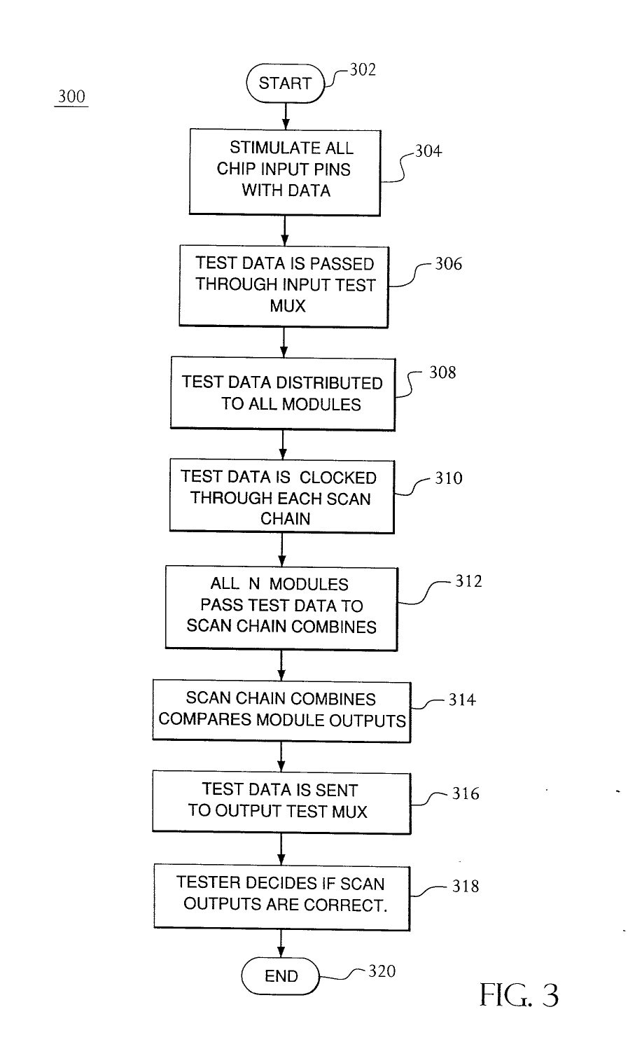

FIG. 3 depicts a flow diagram illustrating another exemplary test data operation that can be performed by the tester on the ASIC in accordance with an embodiment of the present invention. The method 300 is initiated at step 302 and proceeds to step 304 where each of the plurality of chip inputs 122 are stimulated with test data. The method 300 then proceeds to step 306.

At step 306, the test data is passed through the input test mux 102 where the ASIC 100 is put into test mode. Specifically, the ASIC 100 is put into scan mode via the test mode signal 120 of ASIC 100. The input test mux 102 multiplexes the signals and operates ASIC 100 in test mode as opposed to functional mode. The method 300 then proceeds to step 308 where the test data is distributed to all N modules. That is, the N modules are tested in parallel as opposed to being tested sequentially.

At step 310, the test data is clocked through each scan chain at the same time in all N modules. The N modules are tested in parallel but each one of the plurality of registers 114 in each of the N modules pass the test data sequentially. The method 300 then proceeds to step 312.

At step 312 all of the N modules communicate a respective test scan output result to the scan chain combiner 116. Since each of the N modules is the same, each one of the N modules should produce the same test scan output. The method 300 then proceeds to step 314 where the test scan chain combiner 116 compares the scan chain output result of each N module to each other. Majority voting is used to determine which output value should be used. The method 300 then proceeds to step 316.

At step 316 the output values of the test chain combiner 116 are communicated to the output test mux 108 where they are routed to one of the plurality of chip outputs 136. Specifically, at least one of the plurality of chip outputs 128 are assigned as a scan chain output pin in test mode. The output test mux 108 assigns the output pin for use during testing and routes the scan outputs of the test chain combiner 116 to these pins. The method 300 then proceeds to step 318.

At step 318 the tester determines if the scan outputs are correct. If the scan outputs are incorrect the tester will flag the error and notify the manufacturer there is a flaw in the device. The flawed device can be debugged by using the scan module select signals to check which of the N modules produced an error. The test patterns can be regenerated with the ATPG tool as in method 200, with the appropriate scan module select signals defined. After the patterns are generated then the tester can execute the patterns as described above in method 300. The method 300 then proceeds to step 320 where it terminates.

Those skilled in the art can now appreciate from the foregoing description that the broad teachings of the present invention can be implemented in a variety of forms. Therefore, while this invention can be described in connection with particular examples thereof, the true scope of the invention should not be so limited since other modifications will become apparent to the skilled practitioner upon a study of the drawings, specification and the following claims.

What is claimed is:

1. An Integrated Circuit (IC), comprising:
a plurality of modules;
a scan chain combiner coupled to the output of each one of said plurality of modules for selecting one value per scan chain received from said plurality of modules, said value indicative of errors in any of said plurality of modules; and
an output test mux for communicating said value to a tester via a plurality of chip outputs.

2. The Integrated Circuit of claim 1, further including a plurality of chip inputs for receiving test signals from said tester.

3. The Integrated Circuit of claim 2, wherein said test signals comprise test vectors.

4. The Integrated Circuit of claim 1, wherein said scan chain combiner utilizes majority voting logic for comparing the outputs of each one of said plurality of modules to each other.

5. The Integrated Circuit of claim 1, wherein each one of said plurality of modules includes a plurality of registers.

6. The Integrated Circuit of claim 1, further comprising scan chain inputs for performing scan testing on the Integrated Circuit.

7. The Integrated Circuit of claim 6, wherein the scan chain inputs are coupled to each one of the plurality of modules via a source pin.

8. The Integrated Circuit of claim 7, wherein the scan chain inputs are coupled to a plurality of pins.

9. The Integrated Circuit of claim 1, further comprising input muxes for communicating a specific module input signal to a respective one of the plurality of modules.

10. The Integrated Circuit of claim 1, wherein said Integrated Circuit comprises an Application Specific Integrated Circuit (ASIC).

11. The Integrated Circuit of claim 2, wherein said test vectors are processed in parallel by the plurality of modules.

12. The Integrated Circuit of claim 10, further comprising a rest of logic portion for performing the design specific operation of the ASIC.

13. The Integrated Circuit of claim 12, further comprising an output mux for dynamically selecting an output from one of the plurality of modules to communicate to the rest of the logic.

14. The Integrated Circuit of claim 13, wherein said output mux includes a scan module select signal for selecting specific scan outputs from one of the N modules.

15. The Integrated Circuit of claim 12, wherein said output mux includes a scan mode signal for informing each one of a plurality of registers that it will be tested.

16. A method of implementing test capabilities for an Integrated Circuit (IC) comprising:
placing the IC into test mode via the test mode signal of the IC;
allocating scan chains to each one of a plurality of modules;
inserting test vectors through the scan chain;
comparing the outputs of the plurality of modules at a scan chain combiner;
selecting a value as an output for the scan chain combiner, said output value being indicative of at least one error in any of said plurality of modules; and
communicating said output value to a tester via an output test mux.

17. The method of claim 16, further comprising:
communicating the output of one of the plurality of modules to other parts of the IC via an output mux.

18. The method of claim 17, wherein the output of the plurality of modules stimulates the rest of the logic portion of the IC.

19. The method of claim 16, wherein the IC is an Application Specific Integrated Circuit (ASIC).

20. The method of claim 16, wherein said step of selecting comprises using majority voting logic.

21. The method of claim 20, wherein said majority voting logic further comprising selecting the value from the plurality of modules that is in the minority.

22. The method of claim 16, further comprising:
comparing the output scan chain value to an expected value.

23. The method of claim 22, wherein a difference between the expected value and the scan chain value comprises an error.

23. The method of claim 22, further comprising:
comparing the output value of each one of the plurality of modules to the expected value in response to finding an error between the expected value and the scan chain value.

24. The method of claim 17, wherein the output of the plurality of modules stimulates one of the other N−1 modules.
